(19) United States
(12) Patent Application Publication
(10) Pub. No.: US 2018/0233574 A1
(43) Pub. Date: Aug. 16, 2018

(54) SILICON CARBIDE POWER TRANSISTOR APPARATUS AND METHOD OF PRODUCING SAME

(71) Applicant: Purdue Research Foundation, West Lafayette, IN (US)

(72) Inventors: Dallas Todd Morisette, Lafayette, IN (US); Rahul Padavagodu Ramamurthy, West Lafayette, IN (US)

(73) Assignee: Purdue Research Foundation, West Lafayette, IN (US)

(21) Appl. No.: 15/894,911

(22) Filed: Feb. 12, 2018

Related U.S. Application Data
(60) Provisional application No. 62/457,793, filed on Feb. 10, 2017.

(51) Int. Cl. H01L 29/66; H01L 29/16; H01L 29/10; H01L 29/08; H01L 21/04; H01L 21/02; H01L 29/167

(52) U.S. Cl. CPC H01L 29/66068; H01L 29/1608; H01L 29/1095; H01L 29/0865; H01L 21/0475; H01L 29/495; H01L 21/0228; H01L 21/02164; H01L 29/167; H01L 29/66712; H01L 21/049

(57) ABSTRACT

A silicon carbide semiconductor device, wherein the gate insulator is formed by performing a hydrogen etch on an upper exposed surface of a SiC substrate, performing a termination anneal on the upper exposed surface, and depositing a gate insulator material on the upper exposed surface. The SiC substrate may include multiple n-type and p-type doped regions.

### TECHNICAL FIELD

The present U.S. patent application relates to and claims the priority benefit of U.S. Provisional Patent Application Ser. No. 62/457,793, filed Feb. 10, 2017, the contents of which are hereby incorporated by reference in their entirety.

### TECHNICAL FIELD

The present application relates to silicon carbide semiconductor devices, and more specifically, to silicon carbide semiconductor devices having a layer of gate insulating material formed on a silicon carbide substrate.

### BACKGROUND

Silicon carbide (SiC) is an ideal material for power electronics, due to its wide bandgap, high critical field, and high thermal conductivity. Devices utilizing SiC, such as power MOSFETs and Schottky diodes, are particularly competitive against traditional silicon devices for voltages greater than 1 kV. However, there are many important applications requiring lower voltages, such as hybrid electric vehicles, server farm power supplies, and renewable energy power conversion. SiC MOSFET performance in this voltage range is limited by channel resistance, which is determined largely by the electron mobility, a measure of the ease with which electrons are able to move through the material.

Despite efforts in field to identify a solution, the problem of low channel mobility in SiC MOSFETs persists. Most prior art solutions focus on finding a modified process that can more completely passivate the high density of interface traps which result from thermal oxidation of SiC. However, even such modified processes still result in an interface which is unacceptably disordered, or the process is overly complex and expensive. Therefore, improvements are needed in the field.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 depicts a semiconductor power MOSFET device according to one embodiment.

FIG. 2 depicts a semiconductor test device according to one embodiment.

FIG. 3 depicts a process for forming an interface on the upper surface of a SiC region of the device of FIG. 1 according to one embodiment.

FIG. 4 depicts a resulting structure after a hydrogen etch step of the process of FIG. 3.

FIG. 5 depicts a resulting structure after a termination annealing step of the process of FIG. 3.

The attached drawings are for purposes of illustration and are not necessarily to scale.

### DETAILED DESCRIPTION

The present disclosure provides a silicon carbide semiconductor device, wherein the gate insulator is formed by hydrogen etching and appropriately terminating a SiC surface, then depositing an insulating material on the surface using atomic layer deposition.

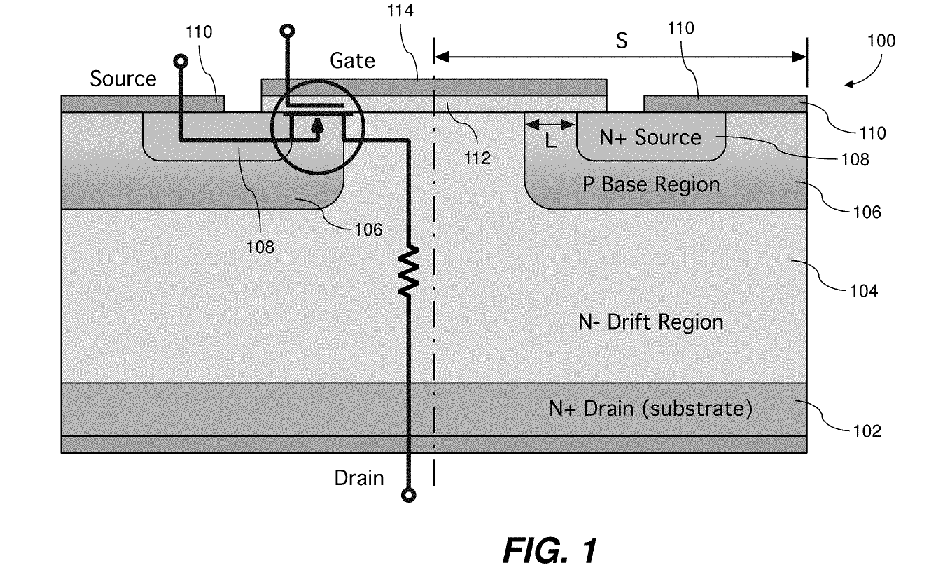

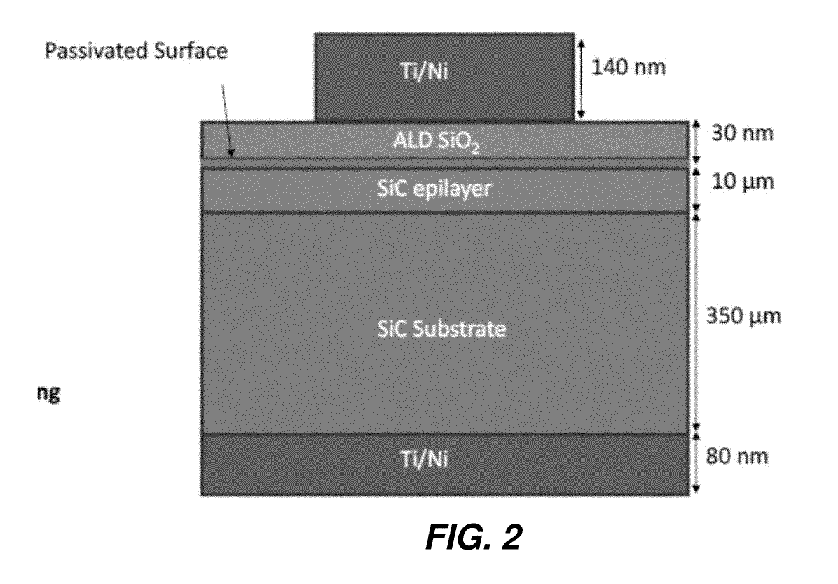

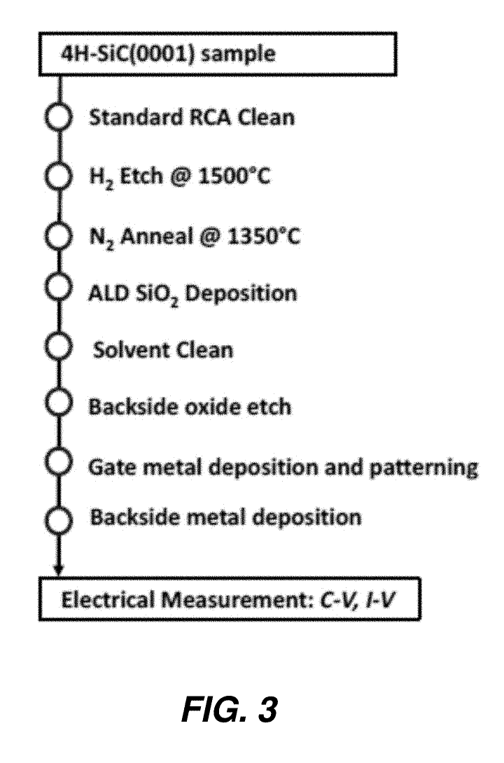

According to one embodiment, the fabrication of a silicon carbide semiconductor device 100, such as a power metal oxide silicon field effect transistor (“MOSFET”) or more specifically, a double-implanted MOSFET or “DMOSFET” as shown in FIGS. 1 and 2 proceeds generally as follows (per FIG. 3). First, a wafer 102 of single crystal, heavily doped (e.g., n-type) SiC (e.g., 4H-SiC or 6H-SiC) is obtained. This back (generally the carbon face) side of this substrate will become the drain terminal of the device 100. On the top (generally silicon face) of the substrate is grown additional crystalline epitaxial layers appropriate for the specific device design. This typically includes a lightly nitrogen doped (n-type) drift layer 104, whose thickness and doping is selected to provide the desired breakdown voltage. This is followed by an aluminum ion implantation to form multiple p-type base regions 106, and by a nitrogen ion implantation within these regions to form the source regions 108, which are isolated from the substrate 102 by the surrounding p-type regions 106. The separation between the edge of the source region 108 and the surrounding base region 106 will form the active channel of the device 100 in the following steps. A heavily doped aluminum implanted region 110 is also used to provide low resistance contact to the base region 106. The device 100 is then subjected to a high temperature implant anneal, typically between 1,500° C. and 1,800° C., to recover the crystal structure damaged by the ion implantation, and to activate the dopants.

The next step is the formation of the gate insulating material 112 (in this example, oxide). In one embodiment, this may begin with an optional sacrificial oxidation step, which grows a thin layer of silicon dioxide, which is subsequently removed with buffered hydrofluoric acid to remove any surface contamination that may be left behind during the ion implantation process. An optional acid cleaning step is then performed, which may include a series of etches in hydrogen peroxide+sulfuric acid, buffered hydrofluoric acid, hydrogen peroxide+ammonium hydroxide, and hydrogen peroxide+hydrochloric acid. This etch is similar to that used in the silicon industry, and is generally known as the “RCA clean”. Following an optional final rinse in DI water, the samples are loaded into a vacuum anneal chamber. The ambient gasses are removed by a vacuum pump, and ultrapure hydrogen is introduced. A hydrogen etch is then performed at between 1,300° C. and 1,600° C. for the desired time at a pressure of approximately 150 mBar, although higher or lower temperatures may be used as required by the application. The hydrogen etch provides recovery of a clean surface with atomically flat terraces and uniform step heights.

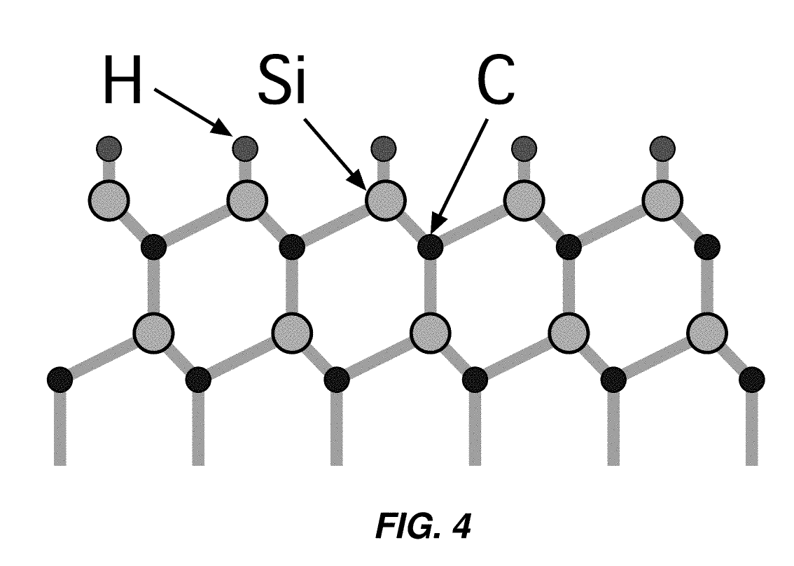

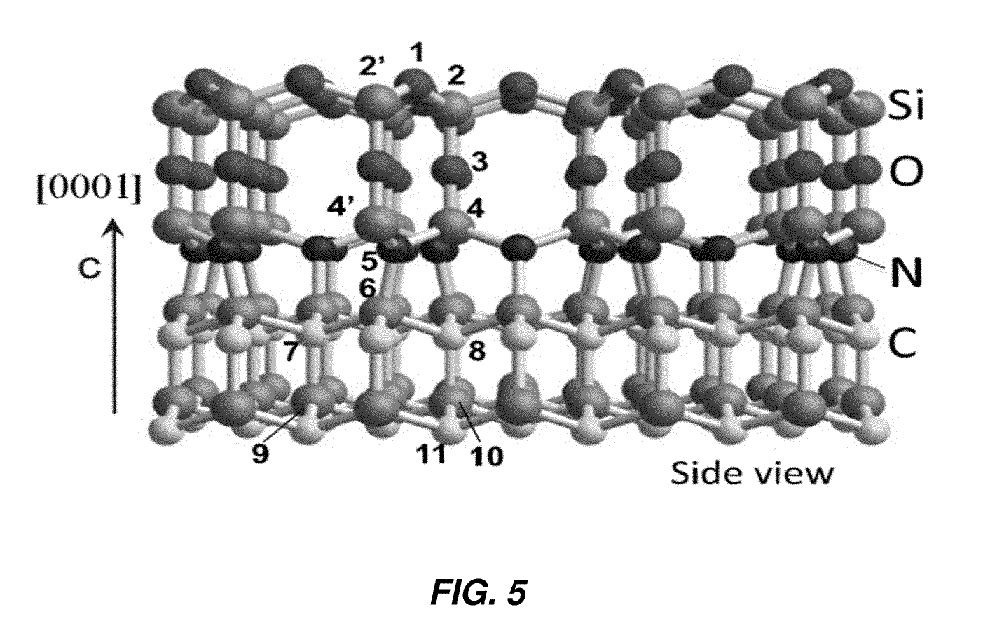

Next, an annealing step is performed, which in certain embodiments, may comprise a hydrogen termination anneal or a silicon oxynitride anneal. Other types of annealing processes may also be used. The hydrogen termination may comprise an anneal at approximately 1,000° C. for between 5 and 30 minutes at a pressure of approximately 900 mBar, resulting in a structure as shown in FIG. 4. The silicon oxynitride annealing may comprise two anneals, first in hydrogen for 5-30 minutes, followed by a second in nitrogen for 5-30 minutes, both at approximately 900 mBar, resulting in a structure as shown in FIG. 5. Following the termination anneal, the sample is cooled in the last ambient until safe to remove from the chamber. After this surface treatment, the sample is transferred to an atomic layer deposition (ALD) system where a gate insulator 112 is deposited at 150-300° C. The use of a low-temperature growth method is critical to ensure the surface is not disrupted by thermal oxidation. In one embodiment this material may be silicon dioxide (SiO2), although other insulating materials or stacks of materials may be utilized.

The use of the ALD technique allows deposition of high quality gate insulators at very low temperatures (˜200° C.) compared with ≥1100° C. required for SiC oxidation. ALD is a thin film deposition technique that is based on the sequential use of a gas phase chemical process. The majority of ALD reactions use two chemicals, typically called precursors. These precursors react with the surface of a material one at a time in a sequential, self-limiting, manner. Through the repeated exposure to separate precursors, a thin film is slowly deposited. The unique feature of ALD is that precursors are exposed to the surface sequentially, rather than in a mixed ambient. In each half cycle a monolayer of precursor reacts with the surface, and is then purged from the system before the second, typically oxidizing precursor is introduced. This cycle repeats as required, with each cycle leaving behind a monolayer of material. This process provides unparalleled control of the deposition process, and with well-engineered precursors allows high-quality, highly conformal thin films to be deposited at very low temperatures compared with conventional chemical vapor deposition (CVD) or oxidation.

ALD also opens up the possibility of using alternative gate insulator materials, and in particular for the introduction of high-κ dielectrics. The channel resistance can be reduced by either increasing the channel electron mobility or by increasing the oxide dielectric constant, assuming the same maximum oxide electric field can be maintained. Therefore, oxidation free deposited gate insulators offer two possible paths to improved channel resistance, through both mobility and electron density.

The remaining steps of the MOSFET process may comprise deposition and patterning of a gate electrode 114 (typically heavily doped polysilicon, or a suitable metal). This is generally followed by an interlayer dielectric deposition followed by patterned etches to open windows for the source and gate contacts. Metal contacts are deposited in these windows (e.g., nickel) and on the back side of the wafer, and annealed at ˜900° C.-1000° C. to form ohmic contacts. Finally a top metal is deposited and patterned to form bond pads for both gate and source electrodes.

It shall be understood that in addition to the illustrated n-channel device 100 (with p-type base region), the above process may be implemented to form p-channel devices (with n-type base region).

It shall be further understood that the above process may be applied to other types of semiconductor devices besides the illustrated vertical DMOSFET. For example, the above process may be implemented to form vertical semiconductor devices (including planar DMOSFETs and trench-based UMOSFETs), lateral semiconductor devices (such as MOSFETs for logic and analog integrated circuits and power LDMOSFETs), and insulated gate bipolar transistors (IGBTs), all of which can be implemented as n-channel or p-channel devices.

The invention is inclusive of combinations of the aspects described herein. References to “a particular aspect” and the like refer to features that are present in at least one aspect of the invention. Separate references to “an aspect” (or “embodiment”) or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A method of manufacturing a semiconductor device, comprising:
a) providing a substrate of single crystal SiC;
b) forming a drift region on the substrate;
c) forming at least one base region in the drift region;
d) forming source regions within the base regions
e) performing a hydrogen etch on the upper exposed surface of the resulting structure;
f) performing a termination anneal on the upper surface; and
g) depositing a gate insulator material on the upper surface using atomic layer deposition.

2. The method of claim 1, wherein the annealing termination comprises a hydrogen termination anneal.

3. The method of claim 1, wherein the annealing termination comprises a silicon oxynitride anneal.

4. The method of claim 1, wherein the gate insulating material comprises silicon dioxide.

5. The method of claim 1, where the substrate of single crystal SiC comprises nitrogen doped (n type) SiC.

6. The method of claim 5, wherein the base region comprises p type SiC.

7. A method of manufacturing a semiconductor device, comprising:
a) performing a hydrogen etch on an upper exposed surface of a SiC substrate;
b) performing a termination anneal on the upper exposed surface; and
c) depositing a gate insulator material on the upper exposed surface.

8. The method of claim 7, wherein said depositing is performed using atomic layer deposition.

9. The method of claim 7, wherein the annealing termination comprises a hydrogen termination anneal.

10. The method of claim 7, wherein the annealing termination comprises a silicon oxynitride anneal.

11. The method of claim 7, wherein the gate insulating material comprises silicon dioxide.

12. The method of claim 7, where the substrate of SiC comprises nitrogen doped (n type) SiC.
